(19) United States
(12) Patent Application Publication
(10) Pub. No.: US 2016/0372609 A1
(43) Pub. Date: Dec. 22, 2016

(54) SCHOTTKY BARRIER DIODE

(71) Applicant: Sumitomo Electric Industries, Ltd., Osaka-shi (JP)

(72) Inventors: Makoto Kiyama, Itami-shi (JP); Masaya Okada, Itami-shi (JP); Susumu Yoshimoto, Itami-shi (JP); Masaki Ueno, Itami-shi (JP)

(21) Appl. No.: 15/185,917

(22) Filed: Jun. 17, 2016

(30) Foreign Application Priority Data
Jun. 19, 2015 (JP) 2015-123833

(51) Int. Cl. H01L 29/872; H01L 29/16; H01L 29/40; H01L 29/167; H01L 29/08; H01L 29/66; H01L 29/207; H01L 29/45; H01L 29/20; H01L 29/06

(52) U.S. Cl. CPC H01L 29/872; H01L 29/2003; H01L 29/1608; H01L 29/402; H01L 29/0619; H01L 29/08; H01L 29/6606; H01L 29/207; H01L 29/452; H01L 29/167; H01L 29/66212

(57) ABSTRACT

A Schottky barrier diode includes a semiconductor layer, a Schottky electrode on a first main surface of the semiconductor layer, the Schottky electrode being in Schottky contact with the semiconductor layer, and an ohmic electrode on a second main surface of the semiconductor layer opposite the first main surface, the ohmic electrode being in ohmic contact with the semiconductor layer. The semiconductor layer contains gallium nitride or silicon carbide. The semiconductor layer includes a drift layer. The drift layer has a thickness of 2 μm or less.

### BACKGROUND OF THE INVENTION

1. Field of the Invention

The present invention relates to a Schottky barrier diode.

The present application claims the priority of Japanese Patent Application No. 2015-123833, filed Jun. 19, 2015, which is incorporated herein by reference in its entirety.

2. Description of the Related Art

Because of their potentially high switching speed and breakdown voltage, vertical Schottky barrier diodes (SBDs) have been used in a variety of applications. In SBDs, an electric current flows in the thickness direction of the semiconductor layer. In order to further improve breakdown voltage and low-loss properties, gallium nitride and silicon carbide are being employed as materials for SBDs. Gallium nitride and silicon carbide have a larger band gap than silicon, which is a widely used traditional material for semiconductor devices. Thus, the use of gallium nitride and silicon carbide as materials of SBDs can improve the breakdown voltage of SBDs and reduce the on-resistance of SBDs (see, for example, Y. Saitoh, et. al., “Extremely Low On-Resistance and High Breakdown Voltage Observed in Vertical GaN Schottky Barrier Diodes with High-Mobility Drift Layers on Low-Dislocation-Density GaN Substrates”, Applied Physics Express, 3, 081001, 2010 and T. Shinohe, “SiC power device”, Toshiba Review, vol. 59, No. 2, 2004, pp. 49-53).

### SUMMARY OF THE INVENTION

A Schottky barrier diode according to the present invention includes a semiconductor layer, a Schottky electrode on a first main surface of the semiconductor layer, the Schottky electrode being in Schottky contact with the semiconductor layer, and an ohmic electrode on a second main surface of the semiconductor layer opposite the first main surface, the ohmic electrode being in ohmic contact with the semiconductor layer. The semiconductor layer contains gallium nitride or silicon carbide. The semiconductor layer includes a drift layer. The drift layer has a thickness of 2 μm or less.

### BRIEF DESCRIPTION OF THE DRAWINGS

FIG. 1 is a schematic cross-sectional view of a Schottky barrier diode according to a first embodiment of the present invention.

FIG. 2 is a flow chart of a method for producing the Schottky barrier diode according to the first embodiment.

FIG. 3 is a schematic cross-sectional view illustrating the method for producing the Schottky barrier diode according to the first embodiment.

FIG. 4 is a schematic cross-sectional view illustrating the method for producing the Schottky barrier diode according to the first embodiment.

FIG. 5 is a schematic cross-sectional view illustrating the method for producing the Schottky barrier diode according to the first embodiment.

FIG. 6 is a schematic cross-sectional view of a Schottky barrier diode according to a second embodiment of the present invention.

FIG. 7 is a flow chart of a method for producing the Schottky barrier diode according to the second embodiment.

FIG. 8 is a schematic cross-sectional view illustrating the method for producing the Schottky barrier diode according to the second embodiment.

FIG. 9 is a schematic cross-sectional view illustrating the method for producing the Schottky barrier diode according to the second embodiment.

FIG. 10 is a schematic cross-sectional view illustrating the method for producing the Schottky barrier diode according to the second embodiment.

FIG. 11 is a schematic cross-sectional view illustrating the method for producing the Schottky barrier diode according to the second embodiment.

FIG. 12 is a graph of the relationship between forward voltage and forward current density.

FIG. 13 is a graph of the relationship between reverse voltage and reverse current density.

### DESCRIPTION OF THE PREFERRED EMBODIMENTS

With recent expansion of the application range of SBDs, SBDs have been studied for applications in which, although a breakdown voltage of more than 1 kV is not required, a relatively high breakdown voltage (in the range of approximately 40 to 300 V, for example) and a higher switching speed (on the order of MHz or GHz) are required. For example, SBDs have been studied for use in rectennas (rectifying antennas) for wireless power transmission. In such applications, SBDs composed of silicon must include a drift layer having a thickness in the range of approximately 4 to 30 μm in order to achieve the breakdown voltage. The product R×Q of forward on-resistance R and responsive charge Q is proportional to the square of the thickness T_{d} of the drift layer. The R×Q of silicon is approximately 100 times larger than that of gallium nitride and approximately 30 times larger than that of silicon carbide. Thus, SBDs composed of silicon and including a drift layer having such a thickness disadvantageously have increased losses.

Although SBDs composed of gallium nitride or silicon carbide as described by Saitoh and Shinohe have a sufficient breakdown voltage, such SBDs have a high forward voltage V_{f} and forward on-resistance R as well as high responsive charge Q and therefore have increased losses at a switching speed on the order of MHz or GHz.

Accordingly, it is an object of the present invention to provide a Schottky barrier diode that causes no significant loss at a switching speed on the order of MHz or GHz.

The present invention can provide a Schottky barrier diode that causes no significant loss even at a switching speed on the order of MHz or GHz.

The embodiments of the present invention will be described below. A Schottky barrier diode (SBD) according to the present application includes a semiconductor layer, a Schottky electrode on a first main surface of the semiconductor layer, the Schottky electrode being in Schottky contact with the semiconductor layer, and an ohmic electrode on a second main surface of the semiconductor layer opposite the first main surface, the ohmic electrode being in ohmic contact with the semiconductor layer. The semiconductor layer contains gallium nitride or silicon carbide. The semiconductor layer includes a drift layer. The drift layer has a thickness of 2 μm or less.

A SBD according to the present application includes a semiconductor layer composed of gallium nitride or silicon carbide. A semiconductor layer composed of gallium nitride or silicon carbide can have a much lower R×Q than silicon layers, thus significantly decreasing loss. A SBD according to the present application includes a drift layer having a thickness T_{d} of 2 μm or less. As described above, R×Q is proportional to the square of the thickness T_{d} of the drift layer. Thus, the thickness T_{d} of 2 μm or less results in a low R×Q.

In particular, a lower Q can result in a lower switching loss at a switching speed on the order of MHz or GHz. Thus, a SBD according to the present application causes no significant loss even at a switching speed on the order of MHz or GHz.

The term “drift layer”, as used herein, refers to a region of a semiconductor layer that acts as an electric current flow path in an on state and is mainly responsible for high breakdown voltage in an off state. In order to further decrease loss, the drift layer can preferably have a thickness of 1.5 μm or less, more preferably 1 μm or less. In order to achieve a necessary breakdown voltage (for example, 40V or more) and stabilize characteristics, the drift layer can have a thickness of 0.5 μm or more.

The SBD may further include an insulating film on the first main surface of the semiconductor layer. The semiconductor layer, insulating film, and Schottky electrode may constitute a field plate structure, in which a portion of the insulating film is disposed between a portion of the Schottky electrode and the semiconductor layer. The field plate structure may have a width of 4 μm or less in a direction perpendicular to the thickness direction of the semiconductor layer and in a direction perpendicular to the inner edge of the field plate structure.

The field plate (FP) structure is an effective means for improving breakdown voltage. However, a FP structure having a great width is slow to respond to high switching speeds. In order to easily respond to high switching speeds, the FP structure may have a width of 4 μm or less. In order to more readily respond to high switching speeds, the FP structure may have a width of 2 μm or less or even 1 μm or less. Furthermore, in order to stabilize the effects of the FP structure, the FP structure may have a width of 0.3 μm or more.

In the SBD, the semiconductor layer may be composed of gallium nitride. For the semiconductor layer composed of gallium nitride, it is difficult in terms of production techniques to form a guard ring in order to improve breakdown voltage. The FP structure is particularly suitable for improving breakdown voltage in such a case.

The SBD may further include a guard ring that is disposed in the drift layer and has a different conductivity type from the drift layer. The guard ring may partly overlap an outer edge region of the Schottky electrode in the thickness direction of the semiconductor layer and extend along the outer edge of the Schottky electrode. The guard ring may have a width of 4 μm or less in a direction perpendicular to the thickness direction of the semiconductor layer and in a direction perpendicular to the inner edge of the guard ring.

The guard ring (GR) structure is an effective means for higher breakdown voltage. However, a GR having a great width is slow to respond to a high switching speed. In order to easily respond to a high switching speed, the GR may have a width of 4 μm or less. In order to more readily respond to high switching speeds, the GR may have a width of 2 μm or less or even 1 μm or less. Furthermore, in order to stabilize the effects of the GR, the GR may have a width of 0.3 μm or more.

In the SBD, the semiconductor layer may be composed of silicon carbide. For the semiconductor layer composed of silicon carbide, the GR is easy to form and is effective in improving breakdown voltage.

In the SBD, the concentration of impurity that generates a majority carrier in the drift layer may range from 1×10¹⁵ to 4×10¹⁷ cm⁻³. In such a concentration range, it is easy to maintain sufficient breakdown voltage and reduce on-resistance. In particular, the concentration of impurity may be less than 5×10¹⁵ cm⁻³ in order to easily respond to high switching speeds.

### First Embodiment

A SBD according to a first embodiment of the present invention will be described below with reference to the accompanying drawings. Note that the same or corresponding parts in the drawings below are denoted by the same reference sign and the description thereof will not be repeated.

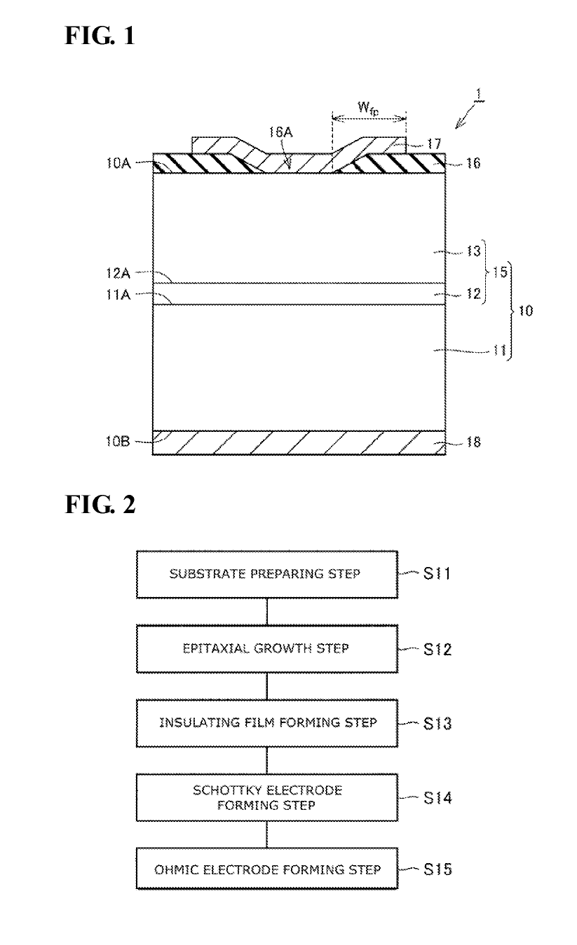

Referring to FIG. 1, a SBD 1 according to the present embodiment includes a substrate 11, a stop layer 12, a drift layer 13, an insulating film 16, a Schottky electrode 17, and an ohmic electrode 18. The stop layer 12 and the drift layer 13 constitute an epitaxial growth layer 15. The substrate 11 and the epitaxial growth layer 15 constitute a semiconductor layer 10.

The substrate 11 is composed of gallium nitride (GaN). The substrate 11 has an n-type conductivity. The substrate 11 contains silicon (Si) as an n-type impurity for forming an n-type carrier, for example. The substrate 11 has a first main surface 11A. The first main surface 11A may be a c-plane or may be a plane having an off-angle of a few degrees with respect to the c-plane.

The stop layer 12 is composed of GaN. The stop layer 12 has an n-type conductivity. The stop layer 12 contains Si as an n-type impurity, for example. The stop layer 12 is in contact with the first main surface 11A of the substrate 11. The stop layer 12 is an epitaxially grown layer on the first main surface 11A of the substrate 11.

The drift layer 13 is composed of GaN. The drift layer 13 has an n-type conductivity. The drift layer 13 contains Si as an n-type impurity, for example. The concentration of n-type impurity in the drift layer 13 is lower than the concentration of n-type impurity in the stop layer 12. For example, the concentration of n-type impurity may range from 1×10¹⁵ to 4×10¹⁷ cm⁻³ or even less than 5×10¹⁵ cm⁻³. The drift layer 13 is in contact with a first main surface 12A of the stop layer 12. The drift layer 13 is an epitaxially grown layer on the first main surface 12A of the stop layer 12. The drift layer 13 has a thickness of 2 μm or less. A main surface of the drift layer 13 opposite the stop layer 12 is a first main surface 10A of the semiconductor layer 10.

The insulating film 16 covers the first main surface 10A of the semiconductor layer 10. The insulating film 16 is in contact with the first main surface 10A of the semiconductor layer 10. The insulating film 16 is composed of an insulator, for example, silicon nitride. The insulating film 16 has an opening 16A, which is a through-hole passing through the insulating film 16 in the thickness direction. The thickness of the insulating film 16 in a region surrounding the opening 16A decreases toward the opening 16A. The insulating film 16 can have a thickness in the range of 50 to 400 nm, for example, in a region other than the region having a decreased thickness. The insulating film 16 has a smaller thickness than insulating films in known GaN-SBDs and contributes to cost reduction. The first main surface 10A of the semiconductor layer 10 is exposed through the opening 16A. In other words, the drift layer 13 is exposed through the opening 16A.

The Schottky electrode 17 is composed of a metal that can be in Schottky contact with the semiconductor layer 10 composed of GaN, for example, nickel (Ni). The Schottky electrode 17 is in contact with the semiconductor layer 10 through the opening 16A and extends on the insulating film 16. The semiconductor layer 10, the insulating film 16, and the Schottky electrode 17 constitute a FP structure, in which a portion of the insulating film 16 is disposed between a portion of the Schottky electrode 17 and the semiconductor layer 10. The FP structure has a width W_{fp} of 4 μm or less in a direction perpendicular to the thickness direction of the semiconductor layer 10 and in a direction perpendicular to the inner edge of the FP structure.

The ohmic electrode 18 is in contact with a second main surface 10B of the semiconductor layer 10 opposite the first main surface 10A. The ohmic electrode 18 is composed of a metal that can be in ohmic contact with the semiconductor layer 10. More specifically, the ohmic electrode 18 is a three-layer metal film, for example, composed of aluminum (Al)/titanium (Ti)/gold (Au).

In the SBD 1 according to the present embodiment, the semiconductor layer 10 composed of GaN can have a much lower loss than Si semiconductor layers. In the SBD 1, the drift layer 13 has a thickness T_{d} of 2 μm or less, thus resulting in a low R×Q. In particular, a lower Q results in a lower switching loss at a switching speed on the order of MHz or GHz. Thus, the SBD 1 causes no significant loss even at a switching speed on the order of MHz or GHz.

In the SBD 1, the FP structure has a width W_{fp} of 4 μm or less. This facilitates response to high switching speeds.

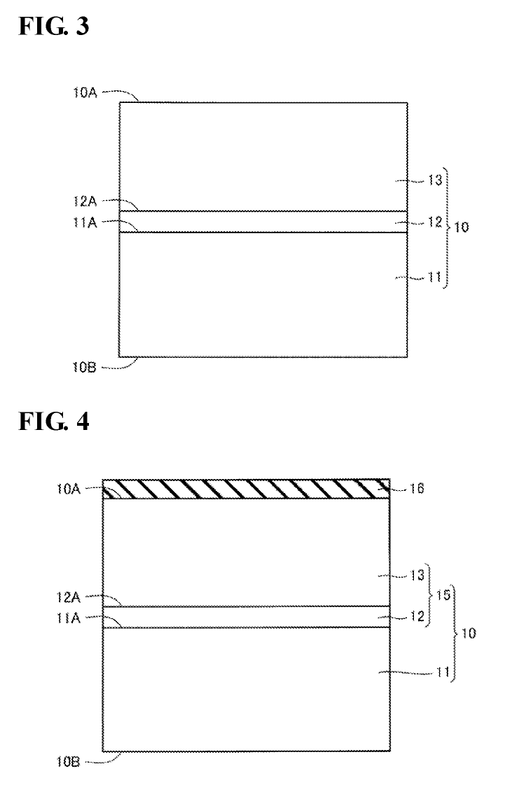

A method for producing the SBD 1 according to the present embodiment will be described below. Referring to FIG. 2, in the method for producing the SBD 1 according to the present embodiment, a substrate preparing step is performed as a first step (S11). Referring to FIG. 3, in the step (S11), the GaN substrate 11, for example, having a diameter of 4 inches (approximately 100 mm) is prepared. More specifically, the GaN substrate 11 is produced by slicing a GaN ingot. A surface of the substrate 11 is polished and washed to ensure the flatness and cleanliness of the first main surface 11A.

Referring to FIG. 2, an epitaxial growth step is then performed as a second step (S12).

Referring to FIG. 3, in the step (S12), the stop layer 12 and the drift layer 13 are formed on the first main surface 11A of the substrate 11 prepared in the step (S11). For example, the stop layer 12 and the drift layer 13 can be formed by metalorganic vapor phase epitaxy (MOVPE). The growth temperature can be 1050° C. The source gas of GaN can be composed of trimethylgallium (TMG) and ammonia. The doping gas of an n-type impurity can be silane. Through these steps, the semiconductor layer 10 can be formed.

Referring to FIG. 2, an insulating film forming step is then performed as a third step (S13). Referring to FIGS. 3 and 4, in the step (S13), the insulating film 16, for example, composed of silicon nitride is formed on the first main surface 10A of the semiconductor layer 10 prepared in the step (S12). For example, the insulating film 16 can be formed by plasma chemical vapor deposition (CVD). The source gas can be composed of silane and ammonia. The insulating film 16 can have a thickness of 0.2 μm.

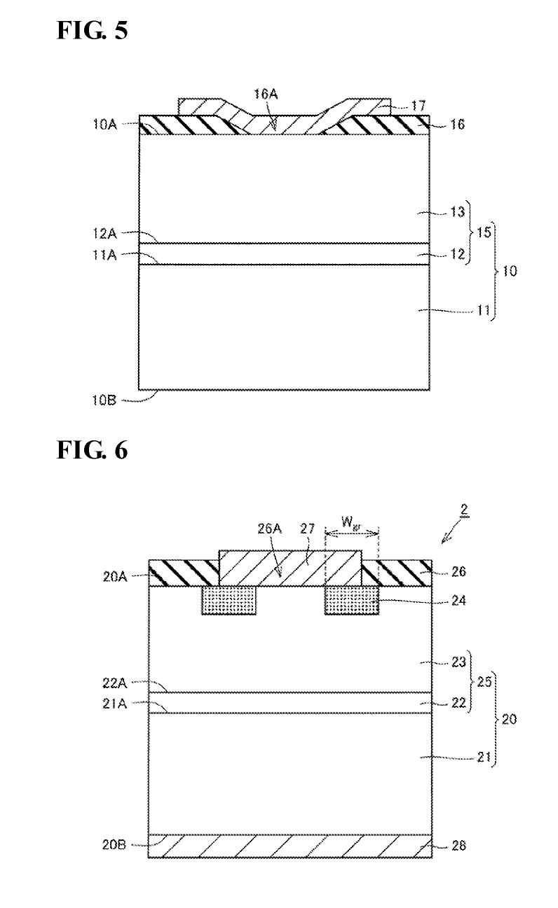

Referring to FIG. 2, a Schottky electrode forming step is then performed as a fourth step (S14). Referring to FIGS. 4 and 5, in the step (S14), the semiconductor layer 10 on which the insulating film 16 is formed in the step (S13) is heat-treated, for example, in a nitrogen atmosphere at 600° C. for 3 minutes. A mask layer having an opening corresponding to the opening 16A is then formed by photolithography. The opening 16A is formed by etching using the mask layer as a mask. For example, the etching can be performed with buffered hydrofluoric acid. After the mask layer is removed, another mask layer having an opening corresponding to the desired shape of the Schottky electrode 17 is formed by photolithography. A metal film composed of a metal constituting the Schottky electrode 17 is formed, for example, by an evaporation method. The metal film is left in the desired region by lift-off to form the Schottky electrode 17. The shape of the Schottky electrode 17 is adjusted such that the FP structure has a width W_{fp} of 4 μm or less.

Referring to FIG. 2, an ohmic electrode forming step is then performed as a fifth step (S15). Referring to FIGS. 5 and 1, in the step (S15), the ohmic electrode 18 is formed on the second main surface 10B of the semiconductor layer 10 on which the Schottky electrode 17 is formed in the step (S14). The ohmic electrode 18 can be formed by forming a metal film composed of a metal constituting the ohmic electrode 18 on the second main surface 10B. For example, the ohmic electrode 18 can be formed after a pad electrode (not shown) is formed on the Schottky electrode 17. Through these steps, the SBD 1 according to the present embodiment can be produced.

Although the thickness of the insulating film of the FP structure in a region surrounding the opening decreases toward the opening in the present embodiment, a SBD according to the present application may have another structure. For example, the thickness of the insulating film in the region surrounding the opening may be almost constant, and the wall surface of the insulating film surrounding the opening may be almost perpendicular to the surface of the semiconductor layer exposed through the opening. Such a FP structure has the effects of improving breakdown voltage similar to those of the structure according to the present embodiment.

### Second Embodiment

A SBD according to a second embodiment of the present invention will be described below. Referring to FIGS. 6 and 1, a SBD 2 according to the second embodiment basically has the same structure and effects as the SBD 1 according to the first embodiment. The SBD 2 according to the second embodiment is different from the SBD 1 according to the first embodiment in that the semiconductor layer is composed of silicon carbide (SiC) and that the high breakdown voltage structure is the GR instead of the FP structure.

Referring to FIG. 6, the SBD 2 according to the present embodiment includes a substrate 21, a stop layer 22, a drift layer 23, an insulating film 26, a Schottky electrode 27, and an ohmic electrode 28. A guard ring (GR) 24 is disposed in the drift layer 23. The stop layer 22 and the drift layer 23 constitute an epitaxial growth layer 25. The substrate 21 and the epitaxial growth layer 25 constitute a semiconductor layer 20.

The substrate 21 is composed of silicon carbide (SiC). The substrate 21 has an n-type conductivity. The substrate 21 contains nitrogen (N) as an n-type impurity for forming an n-type carrier, for example. The substrate 21 has a first main surface 21A. The first main surface 21A may be a c-plane or may be a plane having an off-angle of a few degrees with respect to the c-plane.

The stop layer 22 is composed of SiC. The stop layer 22 has an n-type conductivity. The stop layer 22 contains N as an n-type impurity, for example. The stop layer 22 is in contact with the first main surface 21A of the substrate 21. The stop layer 22 is an epitaxially grown layer on the first main surface 21A of the substrate 21.

The drift layer 23 is composed of SiC. The drift layer 23 has an n-type conductivity. The drift layer 23 contains N as an n-type impurity, for example. The concentration of n-type impurity in the drift layer 23 is lower than the concentration of n-type impurity in the stop layer 22. For example, the concentration of n-type impurity may range from 1×10¹⁵ to 4×10¹⁷ cm⁻³ or even less than 5×10¹⁵ cm⁻³. The drift layer 23 is in contact with a first main surface 22A of the stop layer 22. The drift layer 23 is an epitaxially grown layer on the first main surface 22A of the stop layer 22. The drift layer 23 has a thickness of 2 μm or less. A main surface of the drift layer 23 opposite the stop layer 22 is a first main surface 20A of the semiconductor layer 20.

The insulating film 26 covers the first main surface 20A of the semiconductor layer 20. The insulating film 26 is in contact with the first main surface 20A of the semiconductor layer 20. The insulating film 26 is composed of an insulator, for example, silicon dioxide. The insulating film 26 has an opening 26A, which is a through-hole passing through the insulating film 26 in the thickness direction. The first main surface 20A of the semiconductor layer 20 is exposed through the opening 26A. In other words, the drift layer 23 is exposed through the opening 26A.

The Schottky electrode 27 is composed of a metal that can be in Schottky contact with the semiconductor layer 20 composed of SiC, for example, Ti. The Schottky electrode 27 fills the opening 26A and is in contact with the semiconductor layer 20.

The GR 24 is disposed in the drift layer 23 so as to be in contact with the first main surface 20A of the semiconductor layer 20. A portion of the GR 24 overlaps an outer edge region of the Schottky electrode 27 in the thickness direction of the semiconductor layer 20. The GR 24 extends along the outer edge of the Schottky electrode 27. In a two-dimensional view, the GR 24 partly overlaps the Schottky electrode 27 and has a ring shape surrounding the outer edge of the Schottky electrode 27. The GR 24 has a p-type conductivity. The p-type impurity or impurities in the GR 24 may be Al and/or boron (B). The GR 24 has a width W_{gr} of 4 μm or less in a direction perpendicular to the thickness direction of the semiconductor layer 20 and in a direction perpendicular to the inner edge of the GR 24. For example, the concentration of p-type impurity in the GR 24 can range from 1×10¹⁷ to 1×10¹⁹ cm⁻³. The GR 24 can have a thickness in the range of 50 to 200 nm in the thickness direction of the semiconductor layer 20.

The ohmic electrode 28 is in contact with a second main surface 20B of the semiconductor layer 20 opposite the first main surface 20A. The ohmic electrode 28 is composed of a metal that can be in ohmic contact with the semiconductor layer 20. More specifically, the ohmic electrode 28 is a metal film composed of Ni, for example.

In the SBD 2 according to the present embodiment, the semiconductor layer 20 composed of SiC can have a much lower loss than Si semiconductor layers. In the SBD 2, the drift layer 23 has a thickness T_{d} of 2 μm or less, thus resulting in a low R×Q. In particular, a lower Q results in a lower switching loss at a switching speed on the order of MHz or GHz. Thus, the SBD 2 causes no significant loss even at a switching speed on the order of MHz or GHz.

In the SBD 2, the GR has a width W_{gr} of 4 μm or less. This facilitates response to high switching speeds.

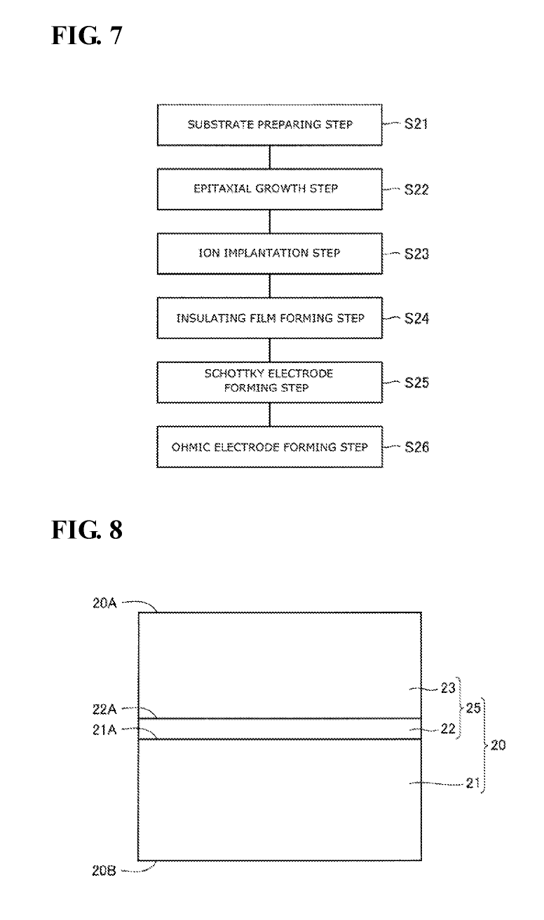

A method for producing the SBD 2 according to the present embodiment will be described below. Referring to FIG. 7, in the method for producing the SBD 2 according to the present embodiment, a substrate preparing step is performed as a first step (S21). Referring to FIG. 8, in the step (S21), the SiC substrate 21, for example, having a diameter of 4 inches (approximately 100 mm) is prepared. More specifically, the SiC substrate 21 is produced by slicing a SiC ingot. A surface of the substrate 21 is polished and washed to ensure the flatness and cleanliness of the first main surface 21A.

Referring to FIG. 7, an epitaxial growth step is then performed as a second step (S22). Referring to FIG. 8, in the step (S22), the stop layer 22 and the drift layer 23 are formed on the first main surface 21A of the substrate 21 prepared in the step (S21). For example, the stop layer 22 and the drift layer 23 can be formed by vapor phase epitaxy using silane and propane as source gases.

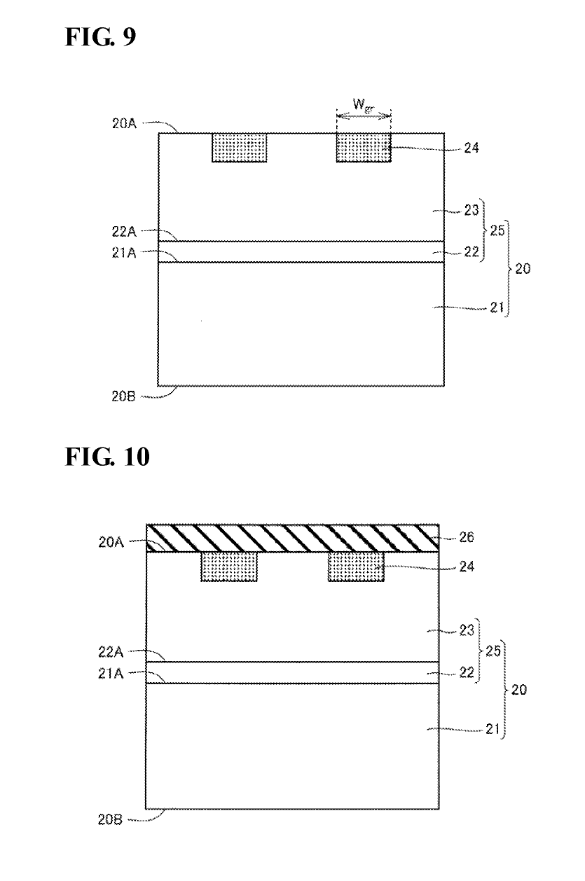

Referring to FIG. 7, an ion implantation step is then performed as a third step (S23). Referring to FIGS. 8 and 9, in the step (S23), the drift layer 23 formed in the step (S22) is subjected to ion implantation to form the GR 24. More specifically, first, a mask layer having an opening corresponding to the desired shape of the GR 24 is formed on the first main surface 20A of the semiconductor layer 20. A p-type impurity, such as Al or B, is introduced into the semiconductor layer 20 (the drift layer 23) by ion implantation using the mask layer as a mask. The ion implantation is performed such that the GR 24 has a width W_{gr} of 4 μm or less. The semiconductor layer 20 is then heated to an appropriate temperature for activation annealing, thereby completing the formation of the GR 24.

Referring to FIG. 7, an insulating film forming step is then performed as a fourth step (S24). Referring to FIGS. 9 and 10, in the step (S24), the insulating film 26 is formed on the first main surface 20A of the semiconductor layer 20 on which the GR 24 is formed in the step (S23). For example, the insulating film 26 can be formed by CVD.

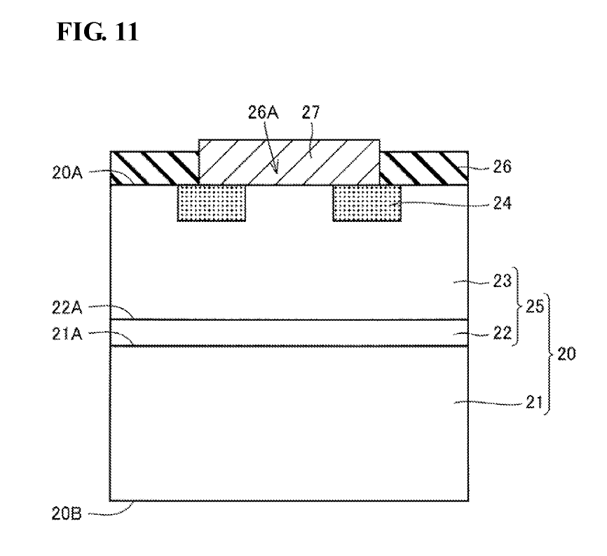

Referring to FIG. 7, a Schottky electrode forming step is then performed as a fifth step (S25). Referring to FIGS. 10 and 11, in the step (S25), a mask layer having an opening corresponding to the opening 26A is then formed by photolithography. The opening 26A is formed by etching using the mask layer as a mask. A metal film composed of a metal constituting the Schottky electrode 27 is then formed, for example, by an evaporation method and is subjected to lift-off to form the Schottky electrode 27.

Referring to FIG. 7, an ohmic electrode forming step is then performed as a sixth step (S26). Referring to FIGS. 11 and 6, in the step (S26), the ohmic electrode 28 is formed on the second main surface 20B of the semiconductor layer 20 on which the Schottky electrode 27 is formed in the step (S25). The ohmic electrode 28 can be formed by forming a metal film composed of a metal constituting the ohmic electrode 28 on the second main surface 20B. For example, the ohmic electrode 28 can be formed after a pad electrode (not shown) is formed on the Schottky electrode 27. Through these steps, the SBD 2 according to the present embodiment can be produced.

### Example 1

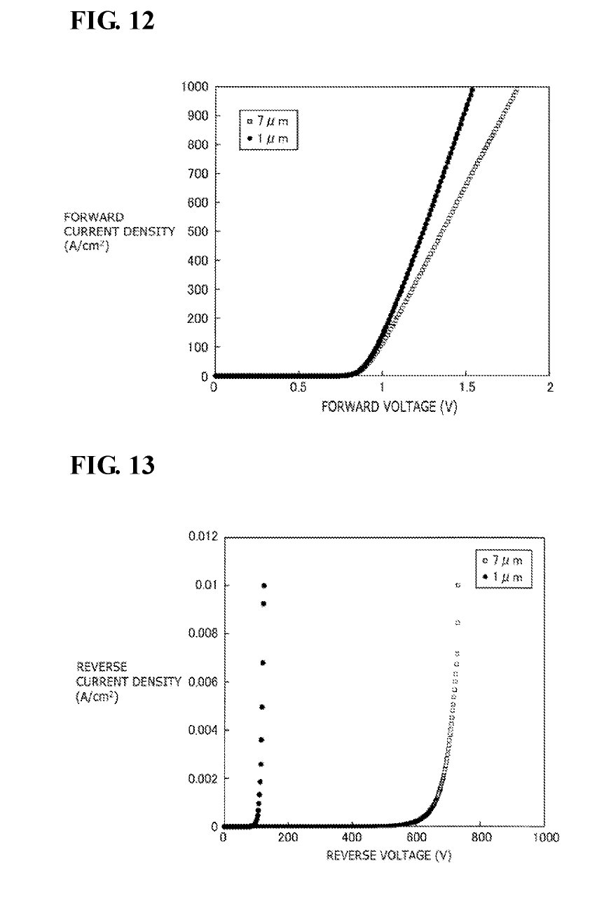

A SBD having the structure of the SBD 1 described in the first embodiment was produced in the same manner as in the first embodiment. The forward and reverse current-voltage (I-V) characteristics of the SBD were determined by experiment. The drift layer 13 had a thickness T_{d} of 1 μm. The concentration of n-type impurity in the drift layer 13 was 4×10¹⁶ cm⁻³ (Example). For comparison purposes, a SBD having the same structure and having a T_{d} of 7 μm was produced in the same manner (Comparative Example) and was subjected to the same experiment. FIGS. 12 and 13 show experimental results.

In FIG. 12, the horizontal axis represents forward voltage, and the vertical axis represents forward current density. In FIG. 13, the horizontal axis represents reverse voltage, and the vertical axis represents reverse current density. In FIGS. 12 and 13, filled circles represent Example in which the T_{d} was 1 μm, and open squares represent Comparative Example in which the T_{d} was 7 μm.

Referring to FIG. 12, the specific on-resistance determined from the inclination of the I-V curve was 0.91 mΩcm² in Comparative Example and was decreased to 0.63 mΩcm² in Example. The forward voltage V_{f} at a forward current density of 500 A/cm² was 1.36 V in the SBD according to Comparative Example and was decreased to 1.24 V in the SBD according to Example. Since the SBD according to Example had a much smaller T_{d} than the SBD according to Comparative Example, the SBD according to Example had low responsive charge in switching and was expected to have a decreased switching loss. Thus, the SBD according to Example causes no significant loss even at a switching speed on the order of MHz or GHz.

Referring to FIG. 13, the breakdown voltage at a reverse current density of 1 mA/cm² was 660 V in the SBD according to Comparative Example and 124 V in the SBD according to Example. Although the SBD according to Example had a lower breakdown voltage than the SBD according to Comparative Example due to its significantly decreased T_{d}, the SBD according to Example still had a sufficient breakdown voltage for some applications.

These experimental results show that a SBD according to the present application causes no significant loss even at a switching speed on the order of MHz or GHz.

### Example 2

The characteristics of a vertical SBD according to the present application and a lateral SBD were compared by experiment. The experimental method is described below.

The SBD 1 having the structure illustrated in FIG. 1 was produced as a vertical SBD according to the present application (a sample 1). The substrate 11 had a diameter of 2 inches and was composed of GaN. The first main surface 11A corresponds to the c-plane of GaN constituting the substrate 11. The substrate 11 had a resistivity of 9 mΩcm and a thickness of 300 μm. The stop layer 12 had a carrier concentration of 2×10¹⁸ cm⁻³ and a thickness of 0.5 μm. The drift layer 13 had a carrier concentration of 5×10¹⁵ cm⁻³ and a thickness of 1 μm. In the stop layer 12 and the drift layer 13, the impurity that generates a majority carrier was Si. The SBD 1 was produced as roughly described below.

The substrate 11 having a diameter of 2 inches (1 inch is approximately 2.5 cm) and an n-type conductivity and composed of GaN was prepared. The first main surface 11A of the substrate 11 corresponded to the c-plane of GaN constituting the substrate 11. The substrate 11 had a resistivity of 9 mΩcm and a thickness of 300 μm.

The stop layer 12 and the drift layer 13 each having an n-type conductivity were epitaxially grown by metalorganic vapor phase epitaxy on the first main surface 11A corresponding to the c-plane of the substrate 11. The concentrations of carrier in the stop layer 12 and the drift layer 13 were 2×10¹⁸ and 5×10¹⁵ cm⁻³, respectively. The stop layer 12 and the drift layer 13 had a thickness of 0.5 and 1 μm, respectively. The growth temperature for the epitaxial growth was 1050° C. The source materials of GaN were TMG and ammonia (NH₃) gas. The n-type dopant was silane (SiH₄). The substrate 11, the stop layer 12, and the drift layer 13 constituted the semiconductor layer 10.

The insulating film 16 was formed on the first main surface 10A of the semiconductor layer 10. The insulating film 16 constituted the field plate (FP) as the termination structure. More specifically, a SiNₓ film having a thickness of 0.2 μm was formed by plasma chemical vapor deposition (CVD) using SiH₄ and NH₃ as source materials.

The semiconductor layer 10 was then heat-treated in a nitrogen (N₂) atmosphere in a rapid thermal annealing (RTA) apparatus. More specifically, the semiconductor layer 10 was heated at 600° C. for 3 minutes. A photoresist film was then formed on the insulating film 16, and an opening was formed in the photoresist film by photolithography. A portion of the insulating film 16 corresponding to the opening was removed by etching. Thus, the opening 16A was formed in the insulating film 16. The insulating film 16 was etched with buffered hydrofluoric acid (a liquid mixture of 50% aqueous HF solution and 40% aqueous NH₄F solution). The etching time was 15 minutes. The opening 16A had a two-dimensionally circular shape having a diameter of 100 μm.

After the photoresist film used for the formation of the opening 16A was removed, a resist mask having an opening corresponding to the shape of the Schottky electrode 17 was formed by photolithography. A Ni layer having a thickness of 50 nm and a Au layer having a thickness of 300 nm were sequentially formed by electron beam (EB) evaporation. The Schottky electrode 17 was formed by lift-off in acetone. The width of an overlap between the Schottky electrode 17 and the insulating film 16 (the SiNₓ film) (the width of the FP structure) was 1 μm.

A pad electrode was then formed on the Schottky electrode 17 through the formation of a metal film by EB evaporation and through photolithography and lift-off in combination. The pad electrode had a three-layer structure of Ti film/platinum (Pt) film/Au film. The Ti film, Pt film, and Au film had a thickness of 50 nm, 100 nm, and 3 μm, respectively. An electrode having a three-layer structure of Al film/Ti film/Au film was formed as the ohmic electrode 18 on the entire second main surface 10B of the substrate 11. The Al film, Ti film, and Au film had a thickness of 200 nm, 50 nm, and 500 nm, respectively. A back-surface pad electrode was formed on the ohmic electrode 18. The back-surface pad electrode had a three-layer structure of Ti film/Pt film/Au film. The Ti film, Pt film, and Au film had a thickness of 50 nm, 100 nm, and 1 μm, respectively.

The structure (stacked layer) thus formed was diced into chips. A chip was mounted on a package by die bonding and wire bonding. The die bonding was performed at 230° C. with a tin (Sn)-silver (Ag) solder. The wire bonding was then performed with an Al wire. Through these steps, the SBD 1 was prepared as a vertical SBD according to the present application (the sample 1).

For comparison purposes, a lateral SBD formed on a GaN template substrate using a sapphire substrate was also prepared (a sample 2). More specifically, first, a GaN layer having a thickness of 2 μm was grown on a sapphire substrate by metalorganic vapor phase epitaxy, thus forming a GaN template substrate. A stop layer and a drift layer were formed on the GaN template substrate in the same manner as in the sample 1.

Mesa etching passing through the drift layer and reaching the stop layer was performed. The depth of the mesa etching was 1.2 μm. The mesa had a two-dimensionally circular shape having a diameter of 150 μm. The mesa etching was performed by inductive coupled plasma (ICP)-reactive ion etching (RIE).

A SiN film was then formed as an insulating film over the drift layer and the stop layer exposed by the mesa etching. A Schottky electrode and a pad electrode were then formed in the same manner as in the sample 1. After a portion of the insulating film covering the stop layer was removed, an ohmic electrode was formed in contact with the exposed stop layer. The resulting structure (stacked layer) was formed into chips in the same manner as in the sample 1. A chip was mounted on a package by die bonding and wire bonding (the sample 2).

The on-resistance R, electrostatic capacitance C, and breakdown voltage V_{b} of the sample 1 and the sample 2 were measured. The on-resistance R was determined from the differential resistance (inclination) of a forward I-V curve in a conductive region (at a current density of 500 A/cm²). The electrostatic capacitance C was measured under zero bias (measurement frequency: 1 MHz). The breakdown voltage V_{b} was determined from the reverse voltage at a current density of 1 mA/cm² in a reverse I-V curve. Table I shows the results.

TABLE I

| | Drift layer | | | | | | | |
|---|---|---|---|---|---|---|---|---|
| | Carrier | | Substrate | | | | | |
| | concentration | Thickness | Thickness | R | C | RC | fc | V_{b} |
| | (cm⁻³) | (μm) | (μm) | (Ω) | (pF) | (ΩpF) | (GHz) | (V) |
| Sample 1 | 5 × 10¹⁵ | 1 | 300 | 5.21 | 1.49 | 7.76 | 20.5 | 104 |
| Sample 2 | 5 × 10¹⁵ | 1 | 300 | 18.2 | 1.55 | 28.2 | 5.6 | 61 |

Referring to Table I, the vertical sample 1 had lower R and higher V_{b} than the lateral sample 2. The sample 1 and the sample 2 had almost the same C. The higher R of the sample 2 is probably caused by increased electrical resistance due to an electric current flow in the transverse direction (in a direction perpendicular to the thickness direction of the drift layer) and by non-uniform electric current distribution due to the concentration of the electric field on the electrode side. The lower V_{b} of the sample 2 is probably caused by surface leakage due to the mesa structure or by a high dislocation density in the drift layer. Since edge dislocation in GaN causes reverse leakage current, the dislocation density may preferably be 1×10⁷ cm⁻² or less. The dislocation density was 1×10⁶ cm⁻² for the sample 1 and 1×10⁹ cm⁻² for the sample 2. The dislocation density was measured by a cathodoluminescence method. The dislocation density can also be measured by a selective etching method.

When a SBD is used at a high switching speed on the order of MHz or GHz (at a high frequency), the RC product (the product of R and C) is considered to be a measure of loss. The f_{c} value can be calculated from the reciprocal of the RC product using the following formula (1).

f_{c}=1/(2πRC) (1)

A higher f_{c} value indicates a lower high-frequency loss. Table I lists the RC product and f_{c} value. The loss will not be significantly increased at a frequency up to approximately one tenth of f_{c}. Thus, for use at a frequency on the order of GHz, an f_{c} value of 10 GHz or more is a criterion of good characteristics. In this regard, the lateral sample 2 had an f_{c} value of less than 10 GHz and therefore had poor characteristics for use at high frequencies, whereas the vertical sample 1 had an f_{c} value of 10 GHz or more and therefore had good characteristics for use at high frequencies.

As described above, unlike the lateral structure, the vertical structure had no increased on-resistance, decreased breakdown voltage, or poor characteristics at high frequencies. Thus, the vertical structure of SBDs according to the present application is superior to the lateral structure for use at high frequencies.

### Example 3

The effects of the thickness of the drift layer on the characteristics of vertical SBDs were examined by experiment. More specifically, samples (samples 3 to 6) having the structure of the sample 1 according to Example 2 (see FIG. 1) were produced. The drift layer 13 of the samples 3 to 6 had a thickness in the range of 0.3 to 5 μm. The characteristics of the samples 3 to 6 were examined in the same manner as in Example 2. The samples 3 to 6 were produced in the same manner as in the sample 1 except that the drift layer 13 formed by epitaxial growth had a different thickness. Table II shows the experimental results.

TABLE II

| | Drift layer | | | | | | | |
|---|---|---|---|---|---|---|---|---|
| | Carrier | | Substrate | | | | | |
| | concentration | Thickness | Thickness | R | C | RC | fc | V_{b} |
| | (cm⁻³) | (μm) | (μm) | (Ω) | (pF) | (ΩpF) | (GHz) | (V) |
| Sample 1 | 5 × 10¹⁵ | 1 | 300 | 5.21 | 1.49 | 7.76 | 20.5 | 104 |
| Sample 3 | 5 × 10¹⁵ | 2 | 300 | 6.51 | 1.47 | 9.57 | 16.6 | 212 |
| Sample 4 | 5 × 10¹⁵ | 5 | 300 | 11.7 | 1.57 | 18.4 | 9.2 | 492 |
| Sample 5 | 5 × 10¹⁵ | 0.5 | 300 | 4.38 | 1.43 | 6.26 | 25.4 | 51 |
| Sample 6 | 5 × 10¹⁵ | 0.3 | 300 | 4.24 | 1.47 | 6.23 | 25.5 | 18 |

Referring to Table II, an increase in the thickness of the drift layer 13 resulted in increased V_{b} and R. The sample 3 in which the drift layer 13 had a thickness of 2 μm had an f_{c} value of 10 GHz or more, whereas the sample 4 in which the drift layer 13 had a thickness of 5 μm had an f_{c} value of less than 10 GHz. This shows that SBDs are suitably used at high frequencies when the drift layer 13 has a thickness of 2 μm or less.

A decrease in the thickness of the drift layer 13 resulted in decreased R and V_{b}. A decrease in the thickness of the drift layer 13 resulted in a decreased loss at high frequencies and a decreased breakdown voltage. In the sample 6 in which the drift layer 13 had a thickness of 0.3 μm, the breakdown voltage was decreased to 18 V. Thus, the sample 6 has limited use. In order to achieve a breakdown voltage of 40 V or more (see the sample 5), the drift layer 13 preferably has a thickness of 0.5 μm or more.

### Example 4

In order to examine the effects of the concentration of carrier in the drift layer and the effects of the electrical resistance of the substrate, samples having the structure of the sample 1 (see FIG. 1) were produced in which the concentration of carrier in the drift layer and the thickness of the substrate were changed. The characteristics of the samples were examined in the same manner as in Examples 2 and 3. More specifically, the drift layer 13 was epitaxially grown at three carrier concentrations (5×10¹⁵, 5×10¹⁶, and 2×10¹⁷ cm⁻³) in the same production process as in the sample 1. The epitaxial wafer was then divided into four pieces such that the substrate 11 had a thickness of 100 μm, 10 μm, or the original thickness (300 μm). SBDs (samples) were produced by using the substrate 11 in the same manner in as the sample 1.

A sample in which the substrate 11 had a thickness of 100 μm was produced as described below. First, the formation of the stop layer 12 to the Schottky electrode 17 was performed in the same manner as in the sample 1. The resulting structure was attached to a polished plate. The substrate 11 was polished with diamond slurry to a thickness of 100 μm. The back-surface (the second main surface 10B) of the substrate 11 was then etched by a thickness of 0.5 μm by ICP-RIE to remove processing damage. The ohmic electrode 18 was then formed in the same manner as in the sample 1.

A sample in which the substrate 11 had a thickness of 10 μm was produced as described below. First, the formation of the stop layer 12 to the Schottky electrode 17 was performed in the same manner as in the sample 1. The entire surface of the Schottky electrode 17 and the insulating film 16 was then covered with a barrier layer composed of a Ni layer, a Pt layer, and a Au layer. A pad electrode and a bonding metal film (for example, a AuSn film) were formed on a device supporting substrate (for example, a silicon substrate) separately prepared. The bonding metal film and the barrier layer were then bonded together with a wafer bonder. The substrate 11 was polished to a thickness of 10 μm in the same manner as in the sample in which the substrate 11 had a thickness of 100 μm. Processing damage was removed, and the ohmic electrode 18 was formed. Table III shows the experimental results.

TABLE III

| | Drift layer | | | | | | | |
|---|---|---|---|---|---|---|---|---|
| | Carrier | | Substrate | | | | | |
| | concentration | Thickness | Thickness | R | C | RC | fc | V_{b} |
| | (cm⁻³) | (μm) | (μm) | (Ω) | (pF) | (ΩpF) | (GHz) | (V) |
| Sample 1 | 5 × 10¹⁵ | 1 | 300 | 5.21 | 1.49 | 7.76 | 20.5 | 104 |
| Sample 7 | 5 × 10¹⁶ | 1 | 300 | 3.99 | 4.58 | 18.3 | 8.7 | 93 |
| Sample 8 | 2 × 10¹⁷ | 1 | 300 | 3.91 | 9.14 | 35.7 | 4.5 | 46 |
| Sample 9 | 5 × 10¹⁵ | 1 | 100 | 2.67 | 1.47 | 3.93 | 40.5 | 99 |
| Sample 10 | 5 × 10¹⁶ | 1 | 100 | 1.44 | 4.68 | 6.74 | 23.6 | 90 |
| Sample 11 | 2 × 10¹⁷ | 1 | 100 | 1.36 | 9.3 | 12.6 | 12.6 | 45 |
| Sample 12 | 5 × 10¹⁵ | 1 | 10 | 1.36 | 1.53 | 2.08 | 76.5 | 96 |
| Sample 13 | 5 × 10¹⁶ | 1 | 10 | 0.137 | 4.71 | 0.65 | 247 | 88 |
| Sample 14 | 2 × 10¹⁷ | 1 | 10 | 0.035 | 9.7 | 0.34 | 472 | 43 |

Referring to Table III, when the substrate 11 had the original thickness of 300 μm, an increase in the concentration of carrier in the drift layer 13 resulted in an increased C. Thus, the f_{c} value decreased with increasing concentration of carrier in the drift layer 13. It is assumed that there is an optimal carrier concentration.

R was much lower when the substrate 11 had a thickness of 100 μm than when the substrate 11 had a thickness of 300 μm. This resulted in an increased f_{c} value and a smaller decrease in f_{c} at high carrier concentrations.

When the thickness of the substrate 11 was decreased to 10 μm, a further decrease in R resulted in a significant increase in f_{c}. Furthermore, f_{c} increased with increasing concentration of carrier in the drift layer 13. Although V_{b} was decreased, V_{b} was in an allowable range of 40 V or more.

These experimental results show that in SBDs according to the present application in which the drift layer has a small thickness, a decrease in the thickness of the substrate contributes to improved characteristics at high frequencies. More specifically, the substrate may have a thickness of 300 μm or less, preferably 100 μm or less, more preferably 10 μm or less.

Although the semiconductor layer includes the substrate in these embodiments and examples, the substrate may have a decreased thickness, as described above, or the semiconductor layer may include no substrate. Such a SBD may be produced by decreasing the thickness of the substrate or removing the substrate by polishing before the formation of the ohmic electrode. When the semiconductor layer includes no substrate, the semiconductor layer may include a drift layer alone. Although SBDs in these embodiments and examples have a high breakdown voltage structure, that is, the field plate structure or guard ring, SBDs according to the present application may have another structure and may have no field plate structure or guard ring in consideration of desired breakdown voltage.

It is to be understood that the embodiments and examples disclosed herein are illustrated by way of example and not by way of limitation in all respects. The scope of the present invention is defined by the appended claims rather than by the description preceding them. All modifications that fall within the scope of the claims and the equivalents thereof are therefore intended to be embraced by the claims.

What is claimed is:

1. A Schottky barrier diode comprising:
a semiconductor layer;
a Schottky electrode on a first main surface of the semiconductor layer, the Schottky electrode being in Schottky contact with the semiconductor layer; and
an ohmic electrode on a second main surface of the semiconductor layer opposite the first main surface, the ohmic electrode being in ohmic contact with the semiconductor layer,
wherein the semiconductor layer contains gallium nitride or silicon carbide,
the semiconductor layer includes a drift layer, and
the drift layer has a thickness of 2 μm or less.

2. The Schottky barrier diode according to claim 1, further comprising:
an insulating film on the first main surface of the semiconductor layer,
wherein the semiconductor layer, the insulating film, and the Schottky electrode constitute a field plate structure, in which a portion of the insulating film is disposed between a portion of the Schottky electrode and the semiconductor layer, and
the field plate structure has a width of 4 μm or less in a direction perpendicular to a thickness direction of the semiconductor layer and in a direction perpendicular to an inner edge of the field plate structure.

3. The Schottky barrier diode according to claim 2, wherein the field plate structure has a width of 0.3 μm or more.

4. The Schottky barrier diode according to claim 2, wherein the semiconductor layer contains gallium nitride.

5. The Schottky barrier diode according to claim 1, further comprising:
a guard ring that is disposed in the drift layer and has a different conductivity type from the drift layer,
wherein the guard ring partly overlaps an outer edge region of the Schottky electrode in the thickness direction of the semiconductor layer and extends along an outer edge of the Schottky electrode, and
the guard ring has a width of 4 μm or less in a direction perpendicular to the thickness direction of the semiconductor layer and in a direction perpendicular to an inner edge of the guard ring.

6. The Schottky barrier diode according to claim 5, wherein the guard ring has a width of 0.3 μm or more.

7. The Schottky barrier diode according to claim 5, wherein the semiconductor layer contains silicon carbide.

8. The Schottky barrier diode according to claim 1, wherein a concentration of impurity that generates a majority carrier in the drift layer ranges from 1×10¹⁵ to 4×10¹⁷ cm⁻³.

9. The Schottky barrier diode according to claim 1, wherein the drift layer has a thickness of 0.5 μm or more.

10. The Schottky barrier diode according to claim 1, wherein the drift layer has a dislocation density of 1×10⁷ cm⁻² or less

11. The Schottky barrier diode according to claim 1, wherein the semiconductor layer further includes a substrate, and the substrate has an n-type conductivity and has a thickness of 300 μm or less.
